(19) United States
(12) Patent Application Publication
(10) Pub. No.: US 2026/0277117 A1
(43) Pub. Date: Sep. 17, 2026

(54) Focus Metrology Method Using Overlay Measurement Tool

(71) Applicant: KLA Corporation, Milpitas, CA (US)

(72) Inventors: Boris Johan Louis HABETS, Dresden (DE); Gaetan DE LIEDEKERKE BEAUFORT, Dresden (DE); Roel GRONHEID, Leuven (BE); Chufan ZHANG, Shanghai (CN); Nadav GUTMAN, Zichron Ya'aqov (IL)

(21) Appl. No.: 19/562,746

(22) Filed: Mar. 10, 2026

Related U.S. Application Data
(60) Provisional application No. 63/770,511, filed on Mar. 12, 2025.

(51) Int. Cl. G03F 7/00; G01B 11/27

(52) U.S. Cl. CPC G03F 7/706831; G01B 11/272; G03F 7/70633; G03F 7/70666; G03F 7/706845; G03F 7/706849; G03F 7/706851; G03F 7/70991

(57) ABSTRACT

A workpiece, such as a semiconductor wafer, is imaged with one or more focus and dose offsets. The workpiece includes overlay targets that have different best focus positions and/or different through focus. A measurement recipe for an optical system is determined for each of the overlay targets such that a focus response is maximized. A neural network can be trained with the measurement recipes for the overlay targets.

### CROSS-REFERENCE TO RELATED APPLICATIONS

This application claims priority to the provisional patent application filed Mar. 12, 2025 and assigned U.S. App. No. 63/770,511, the disclosure of which is hereby incorporated by reference.

### FIELD OF THE DISCLOSURE

This disclosure relates to metrology of workpieces.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it maximizes the return-on-investment for a semiconductor manufacturer.

Fabricating semiconductor devices, such as logic and memory devices, typically includes processing a workpiece like a semiconductor wafer using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etching, deposition, and ion implantation. An arrangement of multiple semiconductor devices fabricated on a single semiconductor wafer may be separated into individual semiconductor devices.

Metrology processes are used at various steps during semiconductor manufacturing to monitor and control the process. Metrology processes are different than inspection processes in that, unlike inspection processes in which defects are detected on workpieces, metrology processes are used to measure one or more characteristics of the workpieces that cannot be determined using existing inspection tools. Metrology processes can be used to measure one or more characteristics of workpieces such that the performance of a process can be determined from the one or more characteristics. For example, metrology processes can measure a dimension (e.g., line width, thickness, etc.) of features formed on the workpieces during the process. In addition, if the one or more characteristics of the workpieces are unacceptable (e.g., out of a predetermined range for the characteristic(s)), the measurements of the one or more characteristics of the workpieces may be used to alter one or more parameters of the process such that additional workpieces manufactured by the process have acceptable characteristic(s).

Defocus in an exposure tool can be difficult to measure based on the overlay targets that are formed. The lines and spaces of the overlay targets can be measured, but it can be challenging to determine if the resulting structure includes a focus or dose error in the exposure tool. While a dose error can be tested, the behavior of focus may not allow a user to determine if positive or negative defocus occurred. A critical dimension scanning electron microscope (CD SEM) can be used to measure specific focus sensitive structures from which a focus error can be derived. These structures may include a combination of dense and isolated lines. However, CD SEM techniques are generally slow and can damage photoresist on a workpiece.

In another example, diffraction-based overlay can be used to measure asymmetric targets such that one side changes as a function of focus. This technique does not use multiple targets, but may need a special reticle to try different targets. Focus responses may not be good and/or robust when using diffraction-based overlay.

In yet another example, an optical critical dimension method was used. First, tools were designed to derive focus error information from the photoresist profile. This method requires model calibration. Since high numerical aperture extreme ultraviolet (EUV) uses a thinner resist and a tighter focus control, these tools may not be sufficiently accurate. Second, image-based overlay was used with symmetric grating. The sensitivity of the center of symmetry due to focus deformation of the grating tends to be weak. Thus, the overlay that is measured is small. Finding the measurement condition for the metrology tool that is most sensitivity to center of symmetry change can be a challenge.

These optical critical dimension methods analyze a signal that measures the stack. Only the top part of that stack is photoresist. A profile of the thin layer of photoresist needs to be measured. The thinner the resist, the smaller that resulting signal will be. Variations in under-layers will change the signal as well. Focus is usually important at the workpiece edge, where there are variations in layer thickness in many layers. The leveling system of the exposure tool may have difficulty finding the right focus because of under-layer variations. These variations also may deteriorate the critical dimension signal.

Therefore, new systems and techniques are needed.

### BRIEF SUMMARY OF THE DISCLOSURE

A method is provided in a first embodiment. The method includes imaging a workpiece with one or more focus and dose offsets. The workpiece includes a plurality of overlay targets that have different best focus positions and/or different through focus. A measurement recipe for an optical system is determined for each of the overlay targets such that a focus response is maximized. A neural network is trained with the measurement recipes for the overlay targets.

The imaging may use a dual camera mode configured to determine focus and wavelength with two cameras. For example, each of the cameras has a different illumination and collection condition.

The measurement recipe may include focus, dose, and/or wavelength.

The method may include determining a design of the overlay targets using simulation such that the overlay targets have the different best focus positions and/or the different through focus.

The overlay targets may include comb-like features.

The imaging may be image-based overlay, diffraction-based overlay, or electron beam overlay.

Focus in an optical system can be controlled using the neural network that is trained according to the method of the first embodiment. One or more optical elements in the optical system may be adjusted to obtain a focus response using the neural network.

Focus in an exposure tool can be controlled using the neural network that is trained according to the method of the first embodiment. The exposure tool may be configured to produce a production workpiece. The neural network can predict a defocus value for a production workpiece.

An optical system is provided in a second embodiment. The optical system includes a light source that generates a beam of light; a stage configured to hold a workpiece in a path of the beam of light; a detector configured to receive the light reflected from the workpiece; at least one optical element disposed in the path of the beam of light between the light source and the stage or between the stage and the detector; and a processor in electronic communication with the detector and the light source. The processor is configured to operate a neural network. The processor is configured to determine a measurement recipe, such as for the optical system, for each of the overlay targets on the workpiece such that a focus response is maximized.

The neural network can be trained using a plurality of measurement recipes for the optical system for the overlay targets such that the focus response is maximized.

The measurement recipes may be based on images of the overlay targets that have different best focus positions and/or different through focus. The images include one or more focus and dose offsets.

The neural network may be configured to determine a defocus value for the workpiece.

The processor may be configured to communicate with an exposure tool such that the exposure tool is adjusted based on the focus response. The exposure tool can be configured to produce a second workpiece after the adjusting.

The processor may be configured to adjust the at least one optical element to obtain a focus response using the neural network.

### DESCRIPTION OF THE DRAWINGS

For a fuller understanding of the nature and objects of the disclosure, reference should be made to the following detailed description taken in conjunction with the accompanying drawings, in which:

FIG. 1 is a flowchart of an embodiment of a method in accordance with the present disclosure;

FIG. 2 illustrates techniques to select focus-sensitive features;

FIG. 3 is an exemplary chart of simulated behavior through focus for various features;

FIG. 4 and FIG. 5 are exemplary target features on a workpiece;

FIG. 6 shows exemplary overlay measurement results on a focus exposure matrix workpiece for different target variations;

FIG. 7 is a chart showing the impact of different measurement conditions on different target variations;

FIG. 8 is an exemplary diagram of a dual camera system;

FIG. 9 is an exemplary landscape captured with a dual camera system wherein the maximum sensitivity to target asymmetry is focus and wavelength locations in the landscape;

FIG. 10 is an exemplary overlay error as a function of measurement setting, which is wavelength and focus of the optical tool in this example;

FIG. 11 is a chart showing exemplary results of training a neural network with the focus exposure matrix workpiece results;

FIG. 12 is a flowchart showing an embodiment of calibration in accordance with the present disclosure;

FIG. 13 is a flowchart of an embodiment of focus control in accordance with the present disclosure; and

FIG. 14 is a block diagram of an embodiment of an optical system in accordance with the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Embodiments disclosed herein accurately and robustly measure exposure tool focus errors, especially for high numerical aperture EUV exposure tools, which can use thin photoresist. This can be used to measure the focus offset of an exposed location to an arbitrarily set reference. A set of overlay targets may be used. These overlay target may have, for example, focus sensitive asymmetric combs that have been optimized for best response by lithographic simulation. Each of the structures of the overlay targets or different parts of the structures of the overlay targets may react differently through focus. The measurement is optimized for maximum focus response using a workpiece with the overlay targets. A two-camera mode may be used such that each camera has a different illumination and collection condition. The measurement result of multiple targets can be used by a neural network to predict an accurate and robust defocus value. While described with image-based overlay, the embodiments disclosed herein also can be applied to diffraction-based overlay or electron beam overlay.

An exposure tool for semiconductor manufacturing can be configured to project patterned radiation onto a photoresist-coated workpiece (e.g., a semiconductor wafer), enabling the formation of fine circuit features during lithographic processing. The exposure tool can include an illumination system that conditions and shapes the radiation beam, a reticle stage that holds and positions a photomask containing the desired pattern, and a projection optical system engineered to minimize aberrations and maintain critical dimension uniformity across the exposure field. A stage controls workpiece alignment and scanning motion to achieve nanometer-level overlay accuracy. The exposure tool may further include a real-time metrology module.

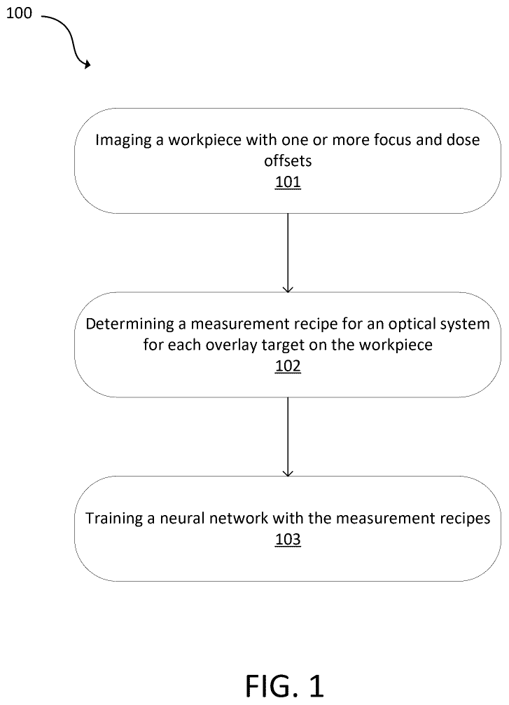

FIG. 1 is a flowchart of an embodiment of a method 100. At 101, a workpiece is imaged with one or more focus and dose offsets. The workpiece includes a plurality of overlay targets that have different best focus positions and/or different through focus. In an instance, the workpiece is a semiconductor wafer, but other workpieces are possible. PROLITH simulations or other simulations may be performed to find features that behave differently through focus. For example, these features may have different best focus positions or have a strong response through focus. For example, critical dimension or pattern placement error will vary as a function of focus offset, which can be used to indicate a potential issue with focus.

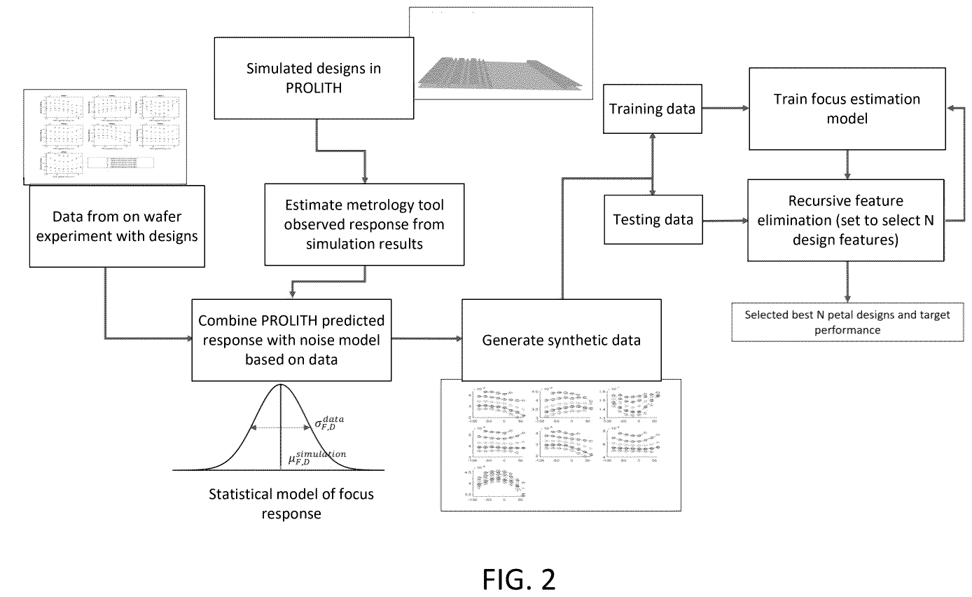

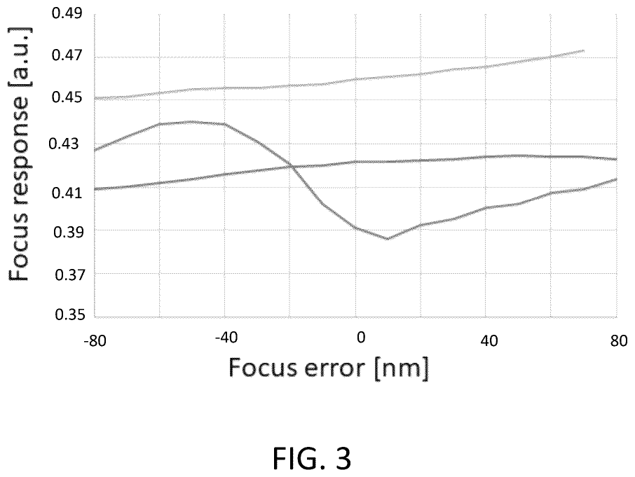

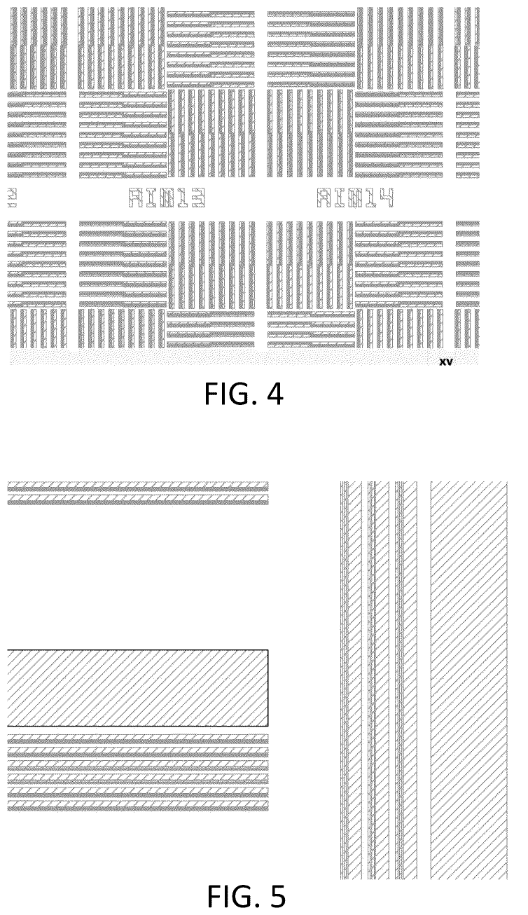

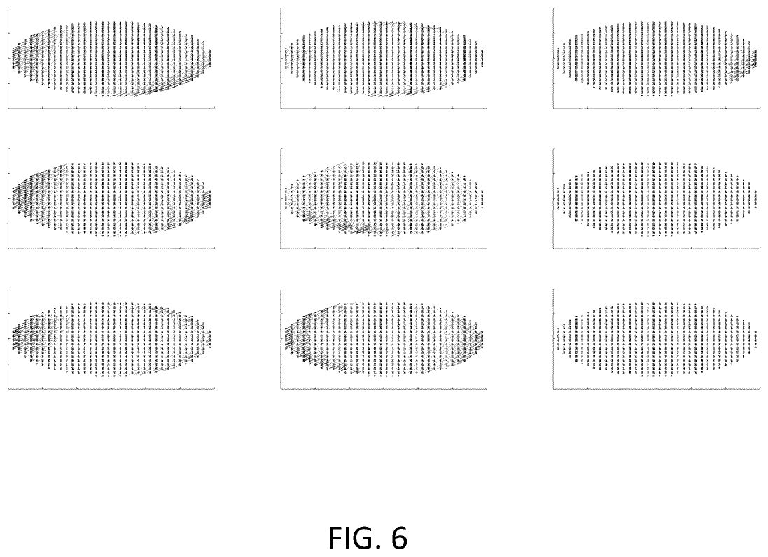

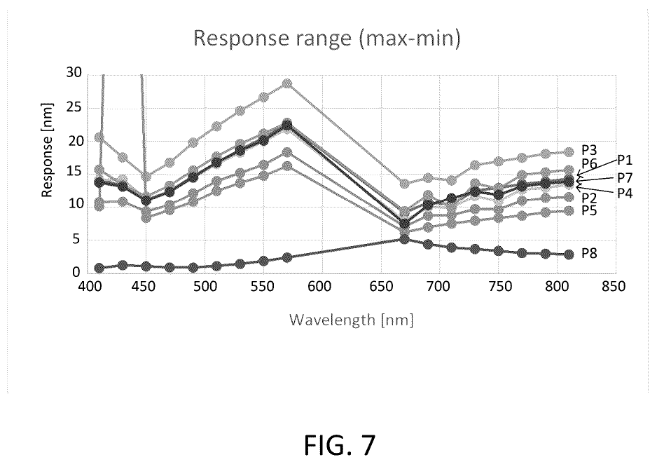

FIG. 2 illustrates techniques to select focus-sensitive features. Synthetic data can be generated based on predicted responses and noise models. Training data and testing data can be used to determine target performance. The design and design features may be petals in an example. FIG. 3 is an exemplary chart of simulated behavior through focus for various features. Each feature in FIG. 3 (which are represented by separate lines) has a different response to focus. A test workpiece (i.e., with a focus exposure matrix) can be exposed to the focus and dose offsets. A focus exposure matrix has a different focus and dose combination in each field. There can be one or multiple targets in each field. Thus, the response to dose and/or focus of some parameter that can be measured from the target can be determined. The focus response is modeled against focus error for various features of the overlay targets in FIG. 3. FIG. 4 and FIG. 5 are exemplary target features on a workpiece that can be designed using the techniques described herein. FIG. 4 shows a complete target while FIG. 5 shows a close-up of two asymmetric comb structures. Targets with combs containing the set of features on different locations within the product reticle can be implemented in a workpiece, such as using a lithography process. While combs are disclosed, other overlay target structures are possible. FIG. 6 shows exemplary overlay measurement results on a focus exposure matrix workpiece for different target variations. In FIG. 6, the y-axis scale ranges from −0.2 to 0.2 and the x-axis scale ranges from −0.15 to 0.15.

PROLITH is a physics-based simulator sold by KLA Corporation. PROLITH uses calibrated, physics-based models to simulate how various types of lithography, including EUV and multiple patterning process techniques, will print on a workpiece, which can eliminate the need to manufacture reticles or print hundreds of test workpieces experimentally. To evaluate process robustness, PROLITH helps users simulate and characterize the impact of multiple lithography variables, such as scanner illumination, exposure dose, focus, or workpiece topography. PROLITH data allow users to adjust and re-optimize additional variables between modeling iterations, such as mask optical proximity correction, scanner source shape, dose, focus, resist thickness, or developer processing.

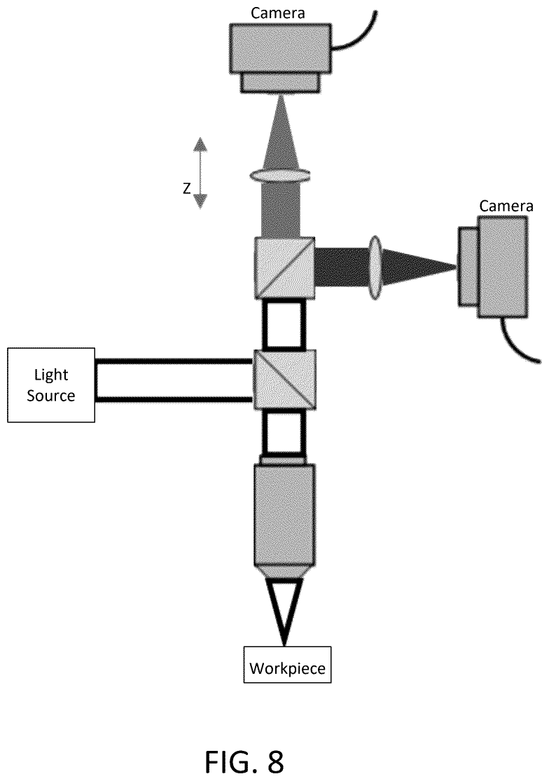

The imaging 101 in FIG. 1 may use a dual camera mode configured to determine focus and wavelength with two cameras, which can check a sensitivity pair layer for focus and wavelength. Each of the cameras may have a different illumination and collection condition. FIG. 8 is an exemplary diagram of a dual camera system. A dual camera system and its operation is described in U.S. Pat. Nos. 11,592,755 and 12,001,148, which are incorporated by reference herein in their entireties. The system in FIG. 8 may have an adjustable position in the Z-axis for Z focus offset. Each camera in FIG. 8 may be operated at a different wavelength and focus position. The beams directed at each camera in FIG. 8 can have different wavelengths. A grating projector can enable separation of focus and wavelength sensitivity from relative camera motion.

Turning back to FIG. 1, a measurement recipe for an optical system for each of the overlay targets is determined at 102 such that a focus response is maximized. The measurement recipe may include focus, dose, and/or wavelength for a feature of the overlay target, overlay target, or workpiece. Usually, the overlay recipe is optimized to be as insensitive as possible against target asymmetry. However, the optimization may try to find maximum sensitivity while retaining robustness in an instance.

In an example of a maximizing focus response, a measurement setup is intentionally selected to show strong sensitivity of the center-of-symmetry (CoS) to wavelength and focus. Normally, low CoS sensitivity across wavelength and focus is used as an indicator of a robust overlay recipe. Here the opposite is performed to maximize focus response. Using the two-camera system of FIG. 8, one camera is kept at a fixed reference condition while the other camera sweeps wavelength and/or focus. The change observed in the CoS then directly reflects the sensitivity to wavelength and/or focus, and these conditions can be used to maximize wavelength and/or focus response for the overlay target.

For example, a measurement recipe that responds strongest to focus variations may be determined. An overlay metric may measure shifts between two structures. Target asymmetry may be interpreted as an overlay error, but this can be an unwanted effect. A metric that directly measures the asymmetry may have a stronger focus response. The recipe may help a manufacturer avoid defocus in an exposure tool.

In another example, a signal to noise ratio for the focus variations may be optimized. The strongest response to focus variations may mean that the signal to noise ratio is minimized.

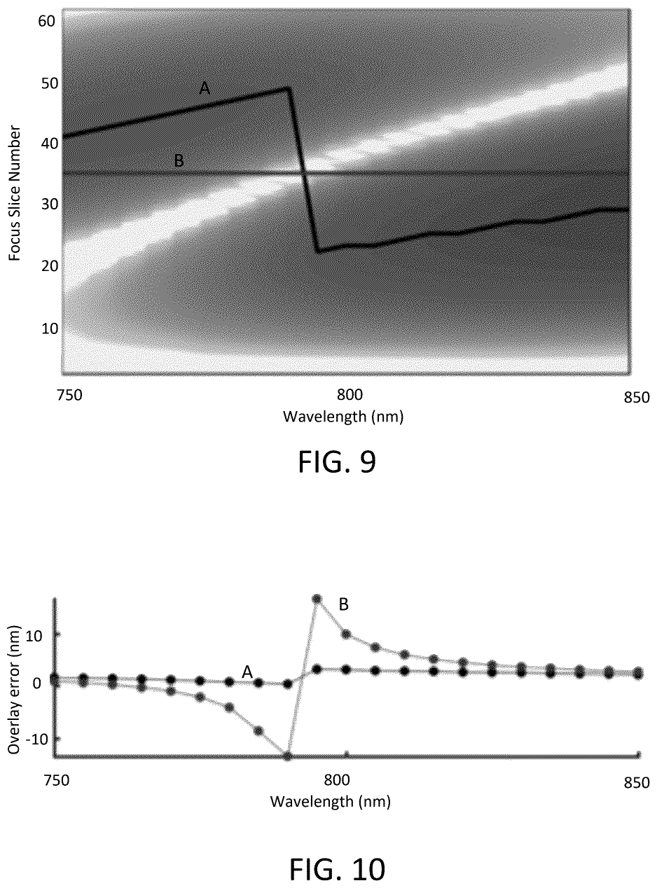

FIG. 9 is an exemplary landscape captured with a dual camera system. The maximum sensitivity to target asymmetry is based on focus and wavelength locations in the landscape. Plotting a center of symmetry landscape can result in the focus and wavelength locations. The maximum sensitivity in FIG. 9 occurs on either side of the transition points (contrast reversal) along the curve designated as curve A. In these regions, small changes in focus or wavelength may lead to relatively large changes in the measured response, making them the most sensitive operating points.

FIG. 10 is an exemplary overlay error as a function of measurement setting, which is wavelength and focus of the optical tool in this example. FIGS. 9 and 10 are directly related and the curves A and B in FIG. 10 correspond to the curves A and B in FIG. 9. In FIG. 9, curve A indicates the best-contrast position for each wavelength, while curve B represents a fixed focus position applied across all wavelengths. FIG. 10 shows the corresponding overlay error for these two cases. The recipe conditions of interest are those that intentionally amplify the overlay error because these provide stronger sensitivity to focus and wavelength variations. Other metrics than overlay error can have similar dependencies.

A neural network is trained with the measurement recipes. For example, the neural network may be trained with the measurement recipe and corresponding feature of the overlay target, overlay target, or workpiece. In an instance, an image of the feature of the overlay target, overlay target, or workpiece is paired with a measurement recipe during training.

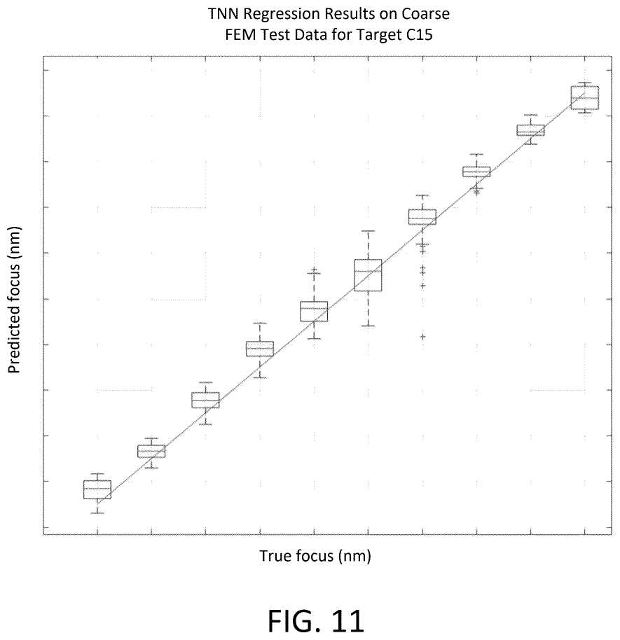

FIG. 11 is a chart showing exemplary results of training a neural network with the focus exposure matrix workpiece results. The diagonal line is a perfect prediction. The true focus on the x-axis ranges from −89.923 nm, −69.9231 nm, −49.9231 nm, −29.9231 nm, −9.92318 nm, 10.0768 nm, 30.0767 nm, 50.0767 nm, 70.0767 nm, and 90.0766 nm. The predicted focus on the y-axis ranges from −100 nm to 100 nm. Once trained, the neural network can be used to control focus in an optical system or an exposure tool. The exposure tool can be an optical system that projects a patterned mask onto a photoresist-coated workpiece using highly-controlled light to define microscale and nanoscale features.

The neural network can predict a defocus value for a production workpiece. One or more optical elements in the optical system can be adjusted based on instructions from the neural network or measurement recipes from the neural network. An optical element may be a lens, polarizing component, spectral filter, spatial filter, reflective optical element, apodizer, beam splitter, or aperture. Furthermore, an exposure tool configured to produce a production workpiece can be adjusted based on the focus response. A recipe can be used that avoids defocus in the exposure tool. Other aspects of the embodiments disclosed herein can be performed on the exposure tool.

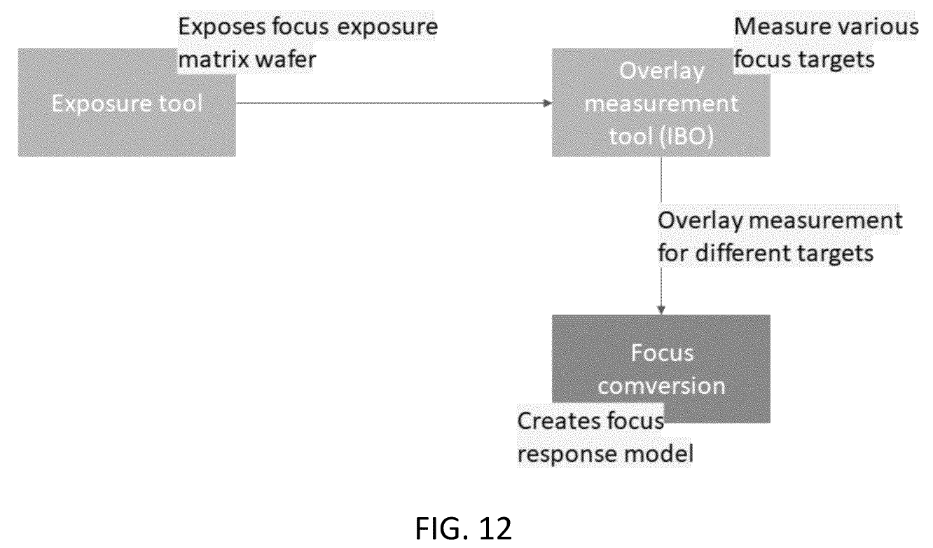

FIG. 12 is a flowchart showing an embodiment of calibration. An exposure tool can expose a focus exposure matrix workpiece. The imaging-based overlay system or another optical system can measure the overlay targets. A focus response model can be determined from the overlay measurements. The focus offset of an exposed location can be measured to determine the response.

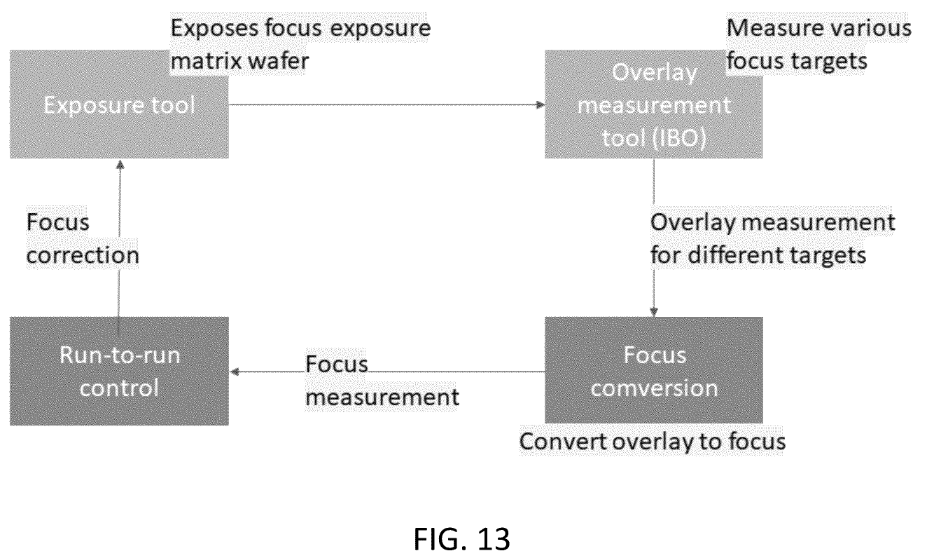

FIG. 13 is a flowchart of an embodiment of focus control. After the focus conversion, the focus measurement can be part of run-to-run control. Focus correction can be communicated to the exposure tool.

Embodiments disclosed herein are independent of photoresist thickness. Sensitivity to under-layer variations is improved compared to previous techniques, which is important for measurements near the edge of the workpiece that are prone to focus errors. Target optimization occurs via simulation, which means the calibration time may be limited to optimizing the recipe and evaluating the focus exposure matrix wafer. Measurements can be performed on an optical system, such as an imaging-based overlay system, which improves throughput.

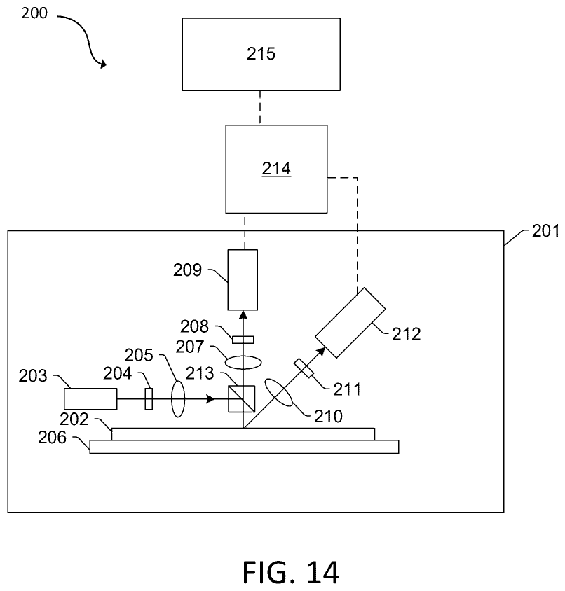

One embodiment of an optical system 200 is shown in FIG. 14, which can be referred to herein as an optical tool or overlay measurement tool. The operation of FIG. 8 is another variation of the optical system 200, and the optical system 200 can be modified to use the design shown in FIG. 8. The optical system 200 includes optical based subsystem 201. In general, the optical based subsystem 201 is configured for generating optical based output for a workpiece 202 by directing light to (or scanning light over) and detecting light from the workpiece 202. In one embodiment, the workpiece 202 includes a wafer. The wafer may include any wafer known in the art. In another embodiment, the workpiece 202 includes a reticle. The reticle may include any reticle known in the art.

In the embodiment of the optical system 200 shown in FIG. 14, optical based subsystem 201 includes an illumination subsystem configured to direct light to workpiece 202. The illumination subsystem includes at least one light source. For example, as shown in FIG. 14, the illumination subsystem includes light source 203. In one embodiment, the illumination subsystem is configured to direct the light to the workpiece 202 at one or more angles of incidence, which may include one or more oblique angles and/or one or more normal angles. For example, as shown in FIG. 14, light from light source 203 is directed through optical element 204 and then lens 205 to workpiece 202 at an oblique angle of incidence. The oblique angle of incidence may include any suitable oblique angle of incidence, which may vary depending on, for instance, characteristics of the workpiece 202.

The optical based subsystem 201 may be configured to direct the light to the workpiece 202 at different angles of incidence at different times. For example, the optical based subsystem 201 may be configured to alter one or more characteristics of one or more elements of the illumination subsystem such that the light can be directed to the workpiece 202 at an angle of incidence that is different than that shown in FIG. 14. In one such example, the optical based subsystem 201 may be configured to move light source 203, optical element 204, and lens 205 such that the light is directed to the workpiece 202 at a different oblique angle of incidence or a normal (or near normal) angle of incidence.

In some instances, the optical based subsystem 201 may be configured to direct light to the workpiece 202 at more than one angle of incidence at the same time. For example, the illumination subsystem may include more than one illumination channel, one of the illumination channels may include light source 203, optical element 204, and lens 205 as shown in FIG. 14 and another of the illumination channels (not shown) may include similar elements, which may be configured differently or the same, or may include at least a light source and possibly one or more other components such as those described further herein. If such light is directed to the workpiece 202 at the same time as the other light, one or more characteristics (e.g., wavelength, polarization, etc.) of the light directed to the workpiece 202 at different angles of incidence may be different such that light resulting from illumination of the workpiece 202 at the different angles of incidence can be discriminated from each other at the detector(s).

In another instance, the illumination subsystem may include only one light source (e.g., light source 203 shown in FIG. 14) and light from the light source may be separated into different optical paths (e.g., based on wavelength, polarization, etc.) by one or more optical elements (not shown) of the illumination subsystem. Light in each of the different optical paths may then be directed to the workpiece 202. Multiple illumination channels may be configured to direct light to the workpiece 202 at the same time or at different times (e.g., when different illumination channels are used to sequentially illuminate the workpiece 202). In another instance, the same illumination channel may be configured to direct light to the workpiece 202 with different characteristics at different times. For example, in some instances, optical element 204 may be configured as a spectral filter and the properties of the spectral filter can be changed in a variety of different ways (e.g., by swapping out the spectral filter) such that different wavelengths of light can be directed to the workpiece 202 at different times. The illumination subsystem may have any other suitable configuration known in the art for directing the light having different or the same characteristics to the workpiece 202 at different or the same angles of incidence sequentially or simultaneously.

In one embodiment, light source 203 may include a broadband plasma (BBP) source. In this manner, the light generated by the light source 203 and directed to the workpiece 202 may include broadband light. However, the light source may include any other suitable light source such as a laser. The laser may include any suitable laser known in the art and may be configured to generate light at any suitable wavelength or wavelengths known in the art. In addition, the laser may be configured to generate light that is monochromatic or nearly-monochromatic. In this manner, the laser may be a narrowband laser. The light source 203 may also include a polychromatic light source that generates light at multiple discrete wavelengths or wavebands.

Light from optical element 204 may be focused onto workpiece 202 by lens 205. Although lens 205 is shown in FIG. 14 as a single refractive optical element, it is to be understood that, in practice, lens 205 may include a number of refractive and/or reflective optical elements that in combination focus the light from the optical element to the workpiece 202. The illumination subsystem shown in FIG. 14 and described herein may include any other suitable optical elements (not shown). Examples of such optical elements include, but are not limited to, polarizing component(s), spectral filter(s), spatial filter(s), reflective optical element(s), apodizer(s), beam splitter(s) (such as beam splitter 213), aperture(s), and the like, which may include any such suitable optical elements known in the art. In addition, the optical based subsystem 201 may be configured to alter one or more of the elements of the illumination subsystem based on the type of illumination to be used for generating the optical based output.

The optical based subsystem 201 may also include a scanning subsystem configured to cause the light to be scanned over the workpiece 202. For example, the optical based subsystem 201 may include stage 206 on which workpiece 202 is disposed during optical based output generation. The scanning subsystem may include any suitable mechanical and/or robotic assembly (that includes stage 206) that can be configured to move the workpiece 202 such that the light can be scanned over the workpiece 202. In addition, or alternatively, the optical based subsystem 201 may be configured such that one or more optical elements of the optical based subsystem 201 perform scanning of the light over the workpiece 202. The light may be scanned over the workpiece 202 in any suitable fashion such as in a serpentine-like path or in a spiral path.

The optical based subsystem 201 further includes one or more detection channels. At least one of the one or more detection channels includes a detector configured to detect light from the workpiece 202 due to illumination of the workpiece 202 by the subsystem and to generate output responsive to the detected light. For example, the optical based subsystem 201 shown in FIG. 14 includes two detection channels, one formed by collector 207, element 208, and detector 209 and another formed by collector 210, element 211, and detector 212. As shown in FIG. 14, the two detection channels are configured to collect and detect light at different angles of collection. In some instances, both detection channels are configured to detect scattered light, and the detection channels are configured to detect light that is scattered at different angles from the workpiece 202. However, one or more of the detection channels may be configured to detect another type of light from the workpiece 202 (e.g., reflected light).

As further shown in FIG. 14, both detection channels are shown positioned in the plane of the paper and the illumination subsystem is also shown positioned in the plane of the paper. Therefore, in this embodiment, both detection channels are positioned in (e.g., centered in) the plane of incidence. However, one or more of the detection channels may be positioned out of the plane of incidence. For example, the detection channel formed by collector 210, element 211, and detector 212 may be configured to collect and detect light that is scattered out of the plane of incidence. Therefore, such a detection channel may be commonly referred to as a “side” channel, and such a side channel may be centered in a plane that is substantially perpendicular to the plane of incidence.

Although FIG. 14 shows an embodiment of the optical based subsystem 201 that includes two detection channels, the optical based subsystem 201 may include a different number of detection channels (e.g., only one detection channel or two or more detection channels). In one such instance, the detection channel formed by collector 210, element 211, and detector 212 may form one side channel as described above, and the optical based subsystem 201 may include an additional detection channel (not shown) formed as another side channel that is positioned on the opposite side of the plane of incidence. Therefore, the optical based subsystem 201 may include the detection channel that includes collector 207, element 208, and detector 209 and that is centered in the plane of incidence and configured to collect and detect light at scattering angle(s) that are at or close to normal to the workpiece 202 surface. This detection channel may therefore be commonly referred to as a “top” channel, and the optical based subsystem 201 may also include two or more side channels configured as described above. As such, the optical based subsystem 201 may include at least three channels (i.e., one top channel and two side channels), and each of the at least three channels has its own collector, each of which is configured to collect light at different scattering angles than each of the other collectors.

As described further above, each of the detection channels included in the optical based subsystem 201 may be configured to detect scattered light. Therefore, the optical based subsystem 201 shown in FIG. 14 may be configured for dark field (DF) output generation for workpieces 202. However, the optical based subsystem 201 may also or alternatively include detection channel(s) that are configured for bright field (BF) output generation for workpieces 202. In other words, the optical based subsystem 201 may include at least one detection channel that is configured to detect light specularly reflected from the workpiece 202. Therefore, the optical based subsystems 201 described herein may be configured for only DF, only BF, or both DF and BF imaging. Although each of the collectors are shown in FIG. 14 as single refractive optical elements, it is to be understood that each of the collectors may include one or more refractive optical die(s) and/or one or more reflective optical element(s).

The one or more detection channels may include any suitable detectors known in the art. For example, the detectors may include photo-multiplier tubes (PMTs), charge coupled devices (CCDs), time delay integration (TDI) cameras, and any other suitable detectors known in the art. The detectors may also include non-imaging detectors or imaging detectors. In this manner, if the detectors are non-imaging detectors, each of the detectors may be configured to detect certain characteristics of the scattered light such as intensity but may not be configured to detect such characteristics as a function of position within the imaging plane. As such, the output that is generated by each of the detectors included in each of the detection channels of the optical based subsystem may be signals or data, but not image signals or image data. In such instances, a processor such as processor 214 may be configured to generate images of the workpiece 202 from the non-imaging output of the detectors. However, in other instances, the detectors may be configured as imaging detectors that are configured to generate imaging signals or image data. Therefore, the optical based subsystem may be configured to generate optical images or other optical based output described herein in a number of ways.

It is noted that FIG. 14 is provided herein to generally illustrate a configuration of an optical based subsystem 201 that may be included in the system embodiments described herein or that may generate optical based output that is used by the system embodiments described herein. The optical based subsystem 201 configuration described herein may be altered to optimize the performance of the optical based subsystem 201 as is normally performed when designing a commercial output acquisition system. In addition, the systems described herein may be implemented using an existing system (e.g., by adding functionality described herein to an existing system). For some such systems, the methods described herein may be provided as optional functionality of the system (e.g., in addition to other functionality of the system). Alternatively, the system described herein may be designed as a completely new system.

The processor 214 may be coupled to the components of the optical system 200 in any suitable manner (e.g., via one or more transmission media, which may include wired and/or wireless transmission media) such that the processor 214 can receive output. The processor 214 may be configured to perform a number of functions using the output. The optical system 200 can receive instructions or other information from the processor 214. The processor 214 and/or the electronic data storage unit 215 optionally may be in electronic communication with an inspection tool, metrology tool, or review tool (not illustrated) to receive additional information or send instructions. For example, the processor 214 and/or the electronic data storage unit 215 can be in electronic communication with a scanning electron microscope.

The processor 214, other system(s), or other subsystem(s) described herein may be part of various systems, including a personal computer system, image computer, mainframe computer system, workstation, network appliance, internet appliance, or other device. The subsystem(s) or system(s) may also include any suitable processor known in the art, such as a parallel processor. In addition, the subsystem(s) or system(s) may include a platform with high-speed processing and software, either as a standalone or a networked tool.

The processor 214 and electronic data storage unit 215 may be disposed in or otherwise part of the optical system 200 or another device. In an example, the processor 214 and electronic data storage unit 215 may be part of a standalone control unit or in a centralized quality control unit. Multiple processors 214 or electronic data storage units 215 may be used.

The processor 214 may be implemented in practice by any combination of hardware, software, and firmware. Also, its functions as described herein may be performed by one unit, or divided up among different components, each of which may be implemented in turn by any combination of hardware, software and firmware. Program code or instructions for the processor 214 to implement various methods and functions may be stored in readable storage media, such as a memory in the electronic data storage unit 215 or other memory. The processor 214 may be a CPU, GPU, or a combination thereof.

If the optical system 200 includes more than one processor 214, then the different subsystems may be coupled to each other such that images, data, information, instructions, etc. can be sent between the subsystems. For example, one subsystem may be coupled to additional subsystem(s) by any suitable transmission media, which may include any suitable wired and/or wireless transmission media known in the art. Two or more of such subsystems may also be effectively coupled by a shared computer-readable storage medium (not shown).

The processor 214 may be configured to perform a number of functions using the output of the optical system 200 or other output. For instance, the processor 214 may be configured to send the output to an electronic data storage unit 215 or another storage medium. The processor 214 may be configured according to any of the embodiments described herein. The processor 214 also may be configured to perform other functions or additional steps using the output of the optical system 200 or using images or data from other sources.

Various steps, functions, and/or operations of optical system 200 and the methods disclosed herein are carried out by one or more of the following: electronic circuits, logic gates, multiplexers, programmable logic devices, ASICs, analog or digital controls/switches, microcontrollers, or computing systems. Program instructions implementing methods such as those described herein may be transmitted over or stored on carrier medium. The carrier medium may include a storage medium such as a read-only memory, a random access memory, a magnetic or optical disk, a non-volatile memory, a solid state memory, a magnetic tape, and the like. A carrier medium may include a transmission medium such as a wire, cable, or wireless transmission link. For instance, the various steps described throughout the present disclosure may be carried out by a single processor 214 or, alternatively, multiple processors 214. Moreover, different sub-systems of the optical system 200 may include one or more computing or logic systems. Therefore, the above description should not be interpreted as a limitation on the present disclosure but merely an illustration.

In an instance, the processor 214 is in communication with the optical system 200. The processor 214 is configured to operate a neural network. For example, the neural network may be trained using a plurality of measurement recipes for the optical system 200 for a plurality of overlay targets such that the focus response is maximized. The measurement recipes may be based on images of the overlay targets that have different best focus positions and/or different through focus. The images can include one or more focus and dose offsets. In an instance, the neural network is configured to determine a defocus value for the workpiece. The optical system 200 can be used to gather the information to train the neural network or can run the neural network on other workpieces, such as production workpieces.

Besides determining a response of the focus, the processor 214 may be configured to adjust at least one optical element in the optical system 200 using the neural network. This can be performed to obtain a focus response. This also can be used to adjust the focus as feedback.

The processor 214 also may be configured to communicate with an exposure tool configured to produce a second workpiece such that the exposure tool is adjusted based on the focus response. The focus response can be determined using the neural network.

An additional embodiment relates to a non-transitory computer-readable medium storing program instructions executable on a controller for performing a computer-implemented method to obtain a focus response in an optical system, as disclosed herein. In particular, as shown in FIG. 14, electronic data storage unit 215 or other storage medium may contain non-transitory computer-readable medium that includes program instructions executable on the processor 214. The computer-implemented method may include any step(s) of any method(s) described herein, including method 100.

A convolutional neural network (CNN) can be used in as the neural network in an embodiment. A CNN is a type of feed-forward artificial neural network in which the connectivity pattern between its neurons (i.e., pixel clusters) is inspired by the organization of the animal visual cortex. Individual cortical neurons respond to stimuli in a restricted region of space known as the receptive field. The receptive fields of different neurons partially overlap such that they tile the visual field. The response of an individual neuron to stimuli within its receptive field can be approximated mathematically by a convolution operation.

Training data may be inputted to model training (e.g., CNN training), which may be performed in any suitable manner. For example, the model training may include inputting the training data to the CNN and modifying one or more parameters of the model until the output of the model is the same as (or substantially the same as) external validation data. Model training may generate one or more trained models, which may then be sent to model selection, which is performed using validation data. The results that are produced by each one or more trained models for the validation data that is input to the one or more trained models may be compared to the validation data to determine which of the models is the best model. For example, the model that produces results that most closely match the validation data may be selected as the best model. Test data may then be used for model evaluation of the model that is selected (e.g., the best model). Model evaluation may be performed in any suitable manner. The best model also may be sent the optical system for use.

Many different types of CNNs may be used in embodiments of the present disclosure. Different CNNs may be used based on certain scanning modes or circumstances. The configuration of a CNN may change based on the simulator configuration, workpiece, image data acquisition subsystem, or predetermined parameters.

Other models can be used neural network. For example, a Bayesian neural network is a probabilistic graphical model that represents a set of variables and their conditional dependencies via a directed acyclic graph. Bayesian networks can take an event that occurred and predict the likelihood that any one of several possible known causes was a contributing factor. Other neural networks also can be used and the embodiments disclosed herein are not limited to these examples.

Each of the steps of the method may be performed as described herein. The methods also may include any other step(s) that can be performed by the processor and/or computer subsystem(s) or system(s) described herein. The steps can be performed by one or more computer systems, which may be configured according to any of the embodiments described herein. In addition, the methods described above may be performed by any of the system embodiments described herein.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A method comprising:
imaging a workpiece with one or more focus and dose offsets, wherein the workpiece includes a plurality of overlay targets that have different best focus positions and/or different through focus;
determining a measurement recipe for an optical system for each of the overlay targets such that a focus response is maximized; and
training a neural network with the measurement recipes for the overlay targets.

2. The method of claim 1, wherein the imaging uses a dual camera mode configured to determine focus and wavelength with two cameras.

3. The method of claim 2, wherein each of the cameras has a different illumination and collection condition.

4. The method of claim 1, wherein the measurement recipe includes focus, dose, and/or wavelength.

5. The method of claim 1, further comprising determining a design of the overlay targets using simulation such that the overlay targets have the different best focus positions and/or the different through focus.

6. The method of claim 1, wherein the overlay targets include comb-like features.

7. The method of claim 1, wherein the imaging is image-based overlay, diffraction-based overlay, or electron beam overlay.

8. A method of controlling focus in an optical system using the neural network that is trained according to the method of claim 1.

9. The method of claim 8, further comprising adjusting one or more optical elements in the optical system to obtain a focus response using the neural network.

10. A method of controlling focus in an exposure tool using the neural network that is trained according to the method of claim 1, wherein the exposure tool is configured to produce a production workpiece.

11. The method of claim 10, wherein the neural network predicts a defocus value for a production workpiece.

12. An optical system comprising:
a light source that generates a beam of light;
a stage configured to hold a workpiece in a path of the beam of light;
a detector configured to receive the light reflected from the workpiece;
at least one optical element disposed in the path of the beam of light between the light source and the stage or between the stage and the detector; and
a processor in electronic communication with the detector and the light source, wherein the processor is configured to operate a neural network, and wherein the processor is configured to determine a measurement recipe for each of the overlay targets on the workpiece such that a focus response is maximized.

13. The optical system of claim 12, wherein the neural network is trained using a plurality of measurement recipes for the optical system for the overlay targets such that the focus response is maximized.

14. The optical system of claim 13, wherein the measurement recipes are based on images of the overlay targets that have different best focus positions and/or different through focus, wherein the images include one or more focus and dose offsets.

15. The optical system of claim 12, wherein the neural network is configured to determine a defocus value for the workpiece.

16. The optical system of claim 12, wherein the processor is configured to communicate with an exposure tool such that the exposure tool is adjusted based on the focus response, wherein the exposure tool is configured to produce a second workpiece after the adjusting.

17. The optical system of claim 12, wherein the processor is configured to adjust the at least one optical element to obtain a focus response using the neural network.
